(19) United States
(12) Patent Application Publication
(10) Pub. No.: US 2019/0123173 A1
(43) Pub. Date: Apr. 25, 2019

(54) PREPARATION METHOD OF BOTTOM-GATE TYPE LOW-TEMPERATURE POLYSILICON TRANSISTOR

(71) Applicant: WUHAN CHINA STAR OPTOELECTRONICS SEMICONDUCTOR DISPLAY TECHNOLOGY CO., LTD., Wuhan, Hubei (CN)

(72) Inventor: Songshan Li, Shenzhen City , Guangdong (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 15/576,200

(22) PCT Filed: Sep. 21, 2017
(86) PCT No.: PCT/CN2017/102585

§ 371 Date: Nov. 21, 2017

(30) Foreign Application Priority Data
Aug. 7, 2017 (CN) 201710670222.8

(51) Int. Cl. H01L 29/66; H01L 29/786; H01L 29/167; H01L 21/265; H01L 21/266; H01L 21/308

(52) U.S. Cl. CPC H01L 29/66765; H01L 29/78678; H01L 21/3085; H01L 21/26513; H01L 21/266; H01L 29/167

(57) ABSTRACT

A preparation method of a bottom-gate type low-temperature polysilicon transistor is disclosed in the present disclosure. The preparation method includes: preparing a first stack structure on a substrate; preparing a polysilicon layer and an etch stop layer in sequence on the first stack structure; patterning the polysilicon layer and the etch stop layer at the same time so that the etch stop layer covers portions of the polysilicon layer; implanting ions into the polysilicon layer that is not covered by the etch stop layer to form a source/drain region of the low-temperature polysilicon transistor. In this way, the present disclosure can simplify the manufacturing process and save the manufacturing cost.

### TECHNICAL FIELD

The present disclosure relates to the technical field of displaying, and particularly, to a preparation method of a bottom-gate type low-temperature polysilicon transistor.

### BACKGROUND

Because low-temperature polysilicon (LTPS) has high electron mobility, desirable sub-threshold swing, a large on/off current ratio and low power consumption, allows for a high pixel density PPI and can be applied to flexible OLEI) substrates, it has received wide attention.

However, the conventional preparation method requires use of one mask to pattern a polysilicon layer and use of another mask to pattern an etch stop layer, so the manufacturing process is complex and the manufacturing cost is high.

### SUMMARY

The present disclosure provides a preparation method of a bottom-gate type low-temperature polysilicon transistor, which can simplify the manufacturing process and save the manufacturing cost.

To solve the aforesaid technical problem, a technical solution adopted by the present disclosure provides a preparation method of a bottom-gate type low-temperature polysilicon transistor, the preparation method including: preparing a first stack structure on a substrate; preparing a polysilicon layer and an etch stop layer in sequence on the first stack structure; patterning the polysilicon layer and the etch stop layer at the same time so that the etch stop layer covers portions of the polysilicon layer, which includes: patterning the polysilicon layer and the etch stop layer by using a semi-transmissive mask, regions of the semi-transmissive mask that correspond to the polysilicon layer having a light transmissivity different from that of regions of the semi-transmissive mask that correspond to the etch stop layer; implanting ions into the polysilicon layer that is not covered by the etch stop layer to form a source/drain region of the low-temperature polysilicon transistor, wherein the ions are one of boron ions, bismuth ions, germanium ions, and cobalt ions.

To solve the aforesaid technical problem, another technical solution adopted by the present disclosure provides a preparation method of a bottom-gate type low-temperature polysilicon transistor, the preparation method including: preparing a first stack structure on a substrate; preparing a polysilicon layer and an etch stop layer in sequence on the first stack structure; patterning the polysilicon layer and the etch stop layer at the same time so that the etch stop layer covers portions of the polysilicon layer; implanting ions into the polysilicon layer that is not covered by the etch stop layer to form a source/drain region of the low-temperature polysilicon transistor.

To solve the aforesaid technical problem, another technical solution adopted by the present disclosure provides a bottom-gate type low-temperature polysilicon transistor, including: a substrate; a first stack structure prepared on the substrate; a patterned polysilicon layer prepared on the first stack structure; a patterned etch stop layer prepared on the polysilicon layer, the etch stop layer covering portions of the polysilicon layer; a second stack structure formed on the polysilicon layer and the etch stop layer, the second stack structure comprising a source/drain electrode layer, a planarization layer, an anode layer, a pixel definition layer and a supporting layer.

The present disclosure has the following benefits: the preparation method of a bottom-gate type low-temperature polysilicon transistor provided in the present disclosure can simplify the manufacturing process and save the manufacturing cost by patterning the polysilicon layer and the etch stop layer at the same time.

### BRIEF DESCRIPTION OF THE DRAWINGS

FIG. 1 is a schematic flowchart diagram of a first embodiment of a preparation method of a bottom-gate type low-temperature polysilicon transistor according to the present disclosure;

FIG. 2 is a schematic flowchart diagram of an embodiment of the block SI shown in FIG. 1;

FIG. 3 is a schematic flowchart diagram of an embodiment of preparing a polysilicon layer;

FIG. 4 is a schematic view of preparing a first stack structure, a polysilicon layer and an etch stop layer in the first embodiment of the preparation method of a bottom-gate type low-temperature polysilicon transistor according to the present disclosure;

FIG. 5 is a schematic view of patterning the polysilicon layer and the etch stop layer in the first embodiment of the preparation method of a bottom-gate type low-temperature polysilicon transistor according to the present disclosure;

FIG. 6 is a schematic view after the polysilicon layer and the etch stop layer have been patterned in the first embodiment of the preparation method of a bottom-gate type low-temperature polysilicon transistor according to the present disclosure;

FIG. 7 is a schematic flowchart diagram of a second embodiment of the preparation method of a bottom-gate type low-temperature polysilicon transistor according to the present disclosure;

FIG. 8 is a schematic flowchart diagram of an embodiment of the block S26 shown in FIG. 7;

FIG. 9 is a schematic structural view of an embodiment of the bottom-gate type low-temperature polysilicon transistor according to the present disclosure.

### DETAILED DESCRIPTION

Hereinbelow, technical solutions of the embodiments of the present disclosure will be described clearly and fully with reference to the attached drawings illustrating the embodiments of the present disclosure. Obviously, the embodiments described herein are only a part of but not all of the embodiments of the present disclosure. All other embodiments that can be obtained by those of ordinary skill in the art from the embodiments of the present disclosure without making creative efforts shall fall within the scope of the present disclosure.

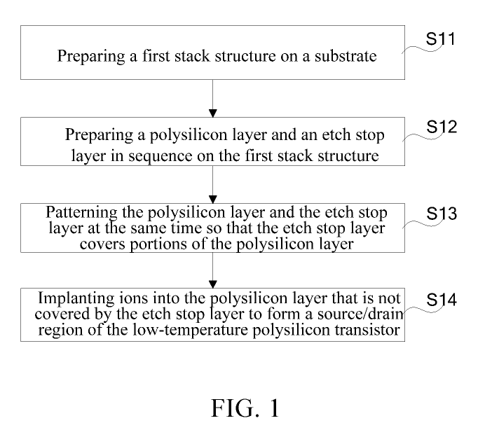

Please refer to FIG. 1, which is a schematic flowchart diagram of an embodiment of a preparation method of a bottom-gate type low-temperature polysilicon transistor according to the present disclosure.

S11: preparing a first stack structure on a substrate.

In this block, a substrate is provided first. The substrate may be of a transparent material. Specifically, the substrate may be a glass substrate, a ceramic substrate, a transparent plastic substrate or a substrate of any form, and the present disclosure has no limitation on this. In this embodiment, the substrate used is a glass substrate.

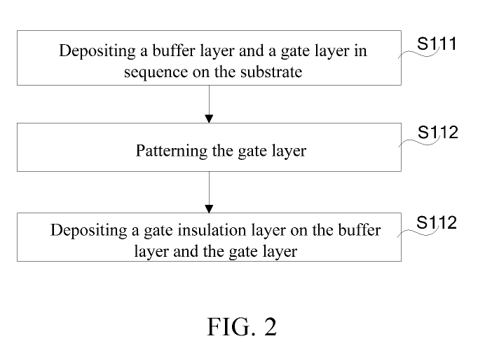

Further, the first stack structure is prepared on the array substrate. As shown in FIG. 2, the block S11 may specifically include the following sub-blocks:

S111: depositing a buffer layer and a gate layer in sequence on the substrate.

Two buffer layers Buffer may be deposited on the substrate, and the material of the buffer layers may include but is not limited to one of SiOx and SiNx, and this embodiment has no limitation on this. The purpose of depositing the buffer layers is to prevent diffusion of metal ions (aluminum ions, barium ions, sodium ions and etc.) in the substrate into the active region of the low-temperature polysilicon during the thermal process, and quality of the backside of the polysilicon layer can be improved by means of the buffer layer thickness or the deposition conditions. Further, the buffer layers are favorable for reducing the thermal conductivity, and reducing the cooling rate of the silicon that is heated by the laser to facilitate crystallization of the silicon.

Further, the gate layer GE is deposited on the buffer layers, and the material of the gate layer may include but is not limited to the metal molybdenum (Mo).

S112: patterning the gate layer.

The gate layer is further patterned through a photolithographic process, and the photolithographic process may further include specific blocks such as resist application, alignment, light exposure and development, and for this, reference may be made to specific operational process of photolithographic processes in the prior art, and no limitation is further made herein.

S12: depositing a gate insulation layer on the buffer layer and the gate layer.

Then the gate insulation layer (GI is deposited on the buffer layers and the patterned gate layer. The material of the gate insulation layer may include but is not limited to one of SiOx and SiNx, and SiOx is used in this embodiment.

S13: preparing a polysilicon layer and an etch stop layer in sequence on the first stack structure.

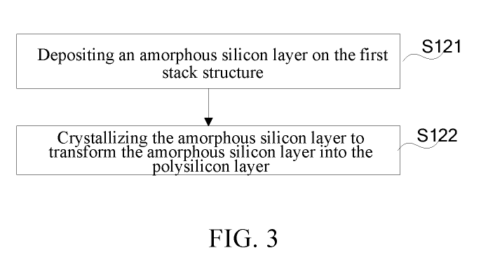

In the block S13, the polysilicon layer is prepared on the stack structure first. Referring to FIG. 3, preparing the polysilicon layer may further include the following blocks:

S131: depositing an amorphous silicon layer on the first stack structure.

Specifically, the amorphous silicon layer is deposited on the gate insulation layer GI in this block.

S132: crystallizing the amorphous silicon layer to transform the amorphous silicon layer into the polysilicon layer.

The amorphous silicon layer is further crystallized. Specifically, transformation of a amorphous silicon film into a polysilicon film may be accomplished by excimer laser annealing (EAL), i.e., by irradiating the amorphous silicon with excimer laser.

Further, the etch stop layer is deposited on the polysilicon layer described above, and the material of the etch stop layer may also be but is not limited to one of SiNx and SiOx.

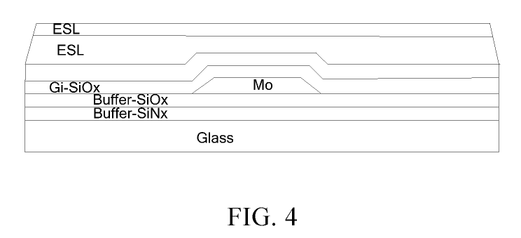

Please refer to FIG. 4 for a schematic structural view of the first stack structure, the polysilicon layer and the etch stop layer. FIG. 4 is a schematic view of preparing the first stack structure, the polysilicon layer and the etch stop layer in the first embodiment of the preparation method of a bottom-gate type low-temperature polysilicon transistor according to the present disclosure.

S14: patterning the polysilicon layer and the etch stop layer at the same time so that the etch stop layer covers portions of the polysilicon layer.

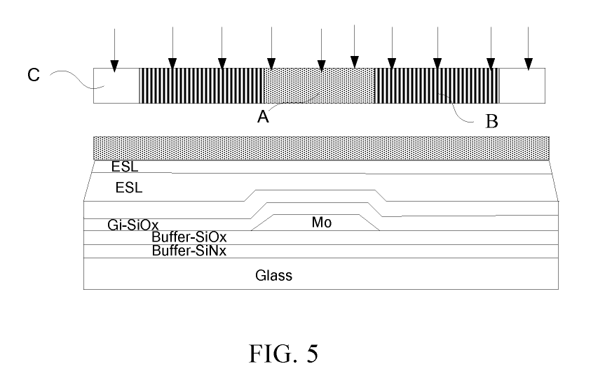

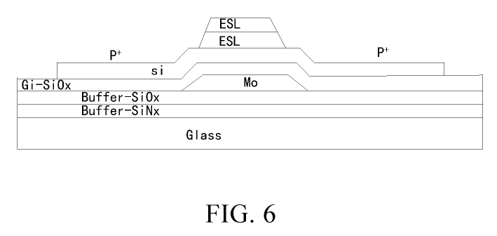

Referring to FIG. 5, in this embodiment, a semi-transmissive mask is used to pattern the polysilicon layer and the etch stop layer, and regions of the semi-transmissive mask that correspond to the polysilicon layer have a light transmissivity different from that of regions of the semi-transmissive mask that correspond to the etch stop layer. Specifically as shown in FIG. 5, a central portion of the semi-transmissive mask is a non-transmissive region A. and a partially transmissive region B and a fully transmissive region C are distributed at two sides of the non-transmissive region A respectively. This semi-transmissive mask is used to pattern the polysilicon layer and the etch stop layer at the same time, and for the patterning, general photolithographic processes including resist application, alignment, light exposure and development may be adopted to pattern the polysilicon layer and the etch stop layer. For the shapes of the patterned polysilicon layer and the patterned etch stop layer, reference may be made to FIG. 6. In FIG. 6, portions of the polysilicon layer and the etch stop layer that correspond to the non-transmissive region A of the semi-transmissive mask remain, portions of the polysilicon layer that correspond to the partially transmissive region B of the semi-transmissive mask remain, and portions of the polysilicon layer and the etch stop layer that correspond to the fully transmissive region C of the semi-transmissive mask are all etched away. After the patterning, the polysilicon layer is partially covered by the etch stop layer.

In this block, patterning the polysilicon layer and the etch stop layer by thesemi-transmissive mask at the same time can simplify the manufacturing process and save the manufacturing cost.

S15: implanting ions into the polysilicon layer that is not covered by the etch stop layer to form a source/drain region of the low-temperature polysilicon transistor.

Further, ions are implanted into the patterned polysilicon layer. The mechanism of ion implantation is as follows: atoms (molecules) to be implanted are ionized, resulting ions are accelerated to strike a solid material so that the ions collide with nuclei and electrons in the material, and as the ions move along a tortuous path, the incident ions lose their energy gradually and finally stay in the material to cause changes of the material in composition, structure and property. The ions used may include but are not limited to one of boron ions, bismuth ions, germanium ions, and cobalt ions. In this embodiment, boron ions are implanted into the patterned polysilicon layer to form a source/drain region P+ of the low-temperature polysilicon transistor.

Further, activation and hydrogenation are performed through annealing. The grain-boundary state between polysilicon grains and the interface state between the polysilicon and the oxide layer (the gate insulation layer) have an impact on the electrical property of the transistor. The hydrogenation fills up the dangling bonds or unsaturated bonds of the polysilicon atoms, the grain-boundary state, the hydrogenated defect layer and the interface state with hydrogen atoms to reduce the number of instabilities, and improve the electrical property, the mobility, the threshold voltage uniformity and the like.

In the embodiment described above, by patterning the polysilicon layer and the etch stop layer at the same time in the preparation process of the bottom-gate type low-temperature polysilicon transistor, the manufacturing process can be simplified and the manufacturing cost can be saved.

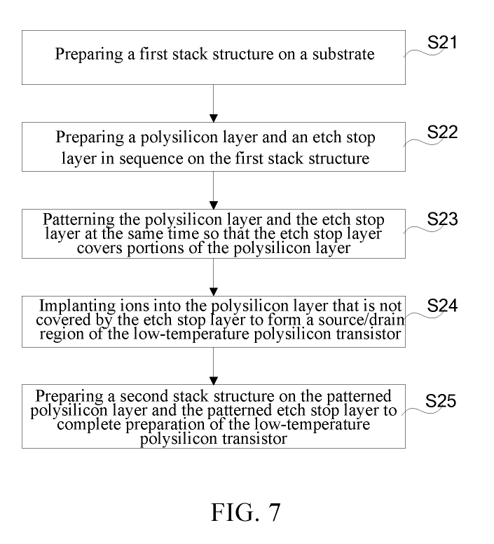

Referring to FIG. 7, FIG. 7 is a schematic flowchart diagram of a second embodiment of the preparation method of a bottom-gate type low-temperature polysilicon transistor according to the present disclosure. This embodiment is an extension of the first embodiment of the preparation method of a bottom-gate type low-temperature polysilicon transistor, therefore similarities with the first embodiment will not be described again. The second embodiment further includes the following sub-blocks:

S21: preparing a first stack structure on a substrate.

S22: preparing a polysilicon layer and an etch stop layer in sequence on the first stack structure.

S23: patterning the polysilicon layer and the etch stop layer at the same time so that the etch stop layer covers portions of the polysilicon layer.

S24: implanting ions into the polysilicon layer that is not covered by the etch stop layer to form a source/drain region of the low-temperature polysilicon transistor.

S25: implanting ions into the polysilicon layer that is not covered by the etch stop layer to form a source/drain region of the low-temperature polysilicon transistor.

S26: preparing a second stack structure on the patterned polysilicon layer and the patterned etch stop layer to complete preparation of the low-temperature polysilicon transistor.

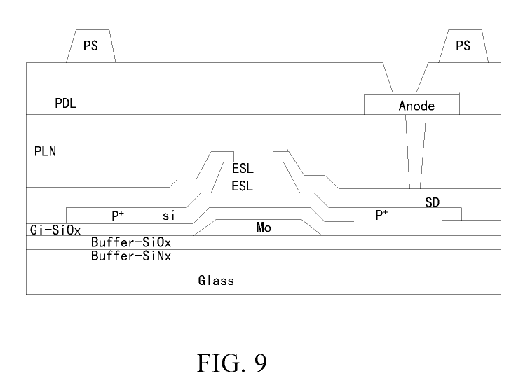

Referring to FIG. 9, the second stack structure includes a source/drain electrode layer (SD), a planarization layer (PLN), an anode layer (Anode), a pixel definition layer (PDL) and a supporting layer (PS).

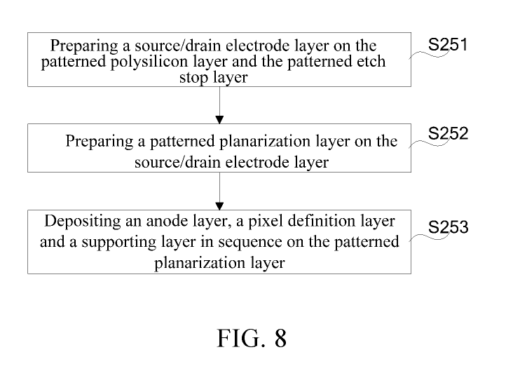

Referring to FIG. 8, the block S25 further includes the following sub-blocks:

S261: preparing a source/drain electrode layer on the patterned polysilicon layer and the patterned etch stop layer.

A source/drain electrode layer is deposited on the patterned polysilicon layer and the patterned etch stop layer and is patterned through a photolithographic process to form a source/drain, wherein the photolithographic process specifically includes such blocks as resist application, alignment, light exposure and development.

S262: preparing a patterned planarization layer on the source/drain electrode layer.

A planarization layer (PLN) is deposited on the source/drain electrode layer and is patterned through a photolithographic process. The planarization layer may be an of organic photoresist material.

S263: depositing an anode layer, a pixel definition layer and a supporting layer in sequence on the patterned planarization layer.

An anode layer (Anode) is deposited on the patterned planarization layer and is patterned through a photolithographic process. Further a pixel definition layer and a supporting layer are deposited in sequence on the patterned anode layer. The pixel definition layer and the supporting layer may also be of an organic photoresist material. Through the aforesaid preparation processes, preparation of the bottom-gate type low-temperature polysilicon transistor is completed.

In the embodiment described above, by patterning the polysilicon layer and the etch stop layer at the same time in the preparation process of the bottom-gate type low-temperature polysilicon transistor, the manufacturing process can be simplified and the manufacturing cost can be saved.

In summary, as will be readily understood by those skilled in the art, the preparation method of a bottom-gate type low-temperature polysilicon transistor according to the present disclosure can simplify the manufacturing process and save the manufacturing cost by patterning the polysilicon layer and the etch stop layer at the same time.

What described above are only the embodiments of the present disclosure, but are not intended to limit the scope of the present disclosure. Any equivalent structures or equivalent process flow modifications that are made according to the specification and the attached drawings of the present disclosure, or any direct or indirect applications of the present disclosure in other related technical fields shall all be covered within the scope of the present disclosure.

1. A preparation method of a bottom-gate type low-temperature polysilicon transistor, wherein the preparation method comprises:
preparing a first stack structure on a substrate;
preparing a polysilicon layer and an etch stop layer in sequence on the first stack structure;
patterning the polysilicon layer and the etch stop layer at the same time so that the etch stop layer covers portions of the polysilicon layer, which comprises:
patterning the polysilicon layer and the etch stop layer by using a semi-transmissive mask, regions of the semi-transmissive mask that correspond to the polysilicon layer having a light transmissivity different from that of regions of the semi-transmissive mask that correspond to the etch stop layer;
implanting ions into the polysilicon layer that is not covered by the etch stop layer to form a source/drain region of the low-temperature polysilicon transistor, wherein the ions are one of boron ions, bismuth ions, germanium ions, and cobalt ions.

2. The preparation method of claim 1, wherein preparing the polysilicon layer on the first stack structure comprises:
depositing an amorphous silicon layer on the first stack structure;
crystallizing the amorphous silicon layer to transform the amorphous silicon layer into the polysilicon layer.

3. The preparation method of claim 2, wherein crystallizing the amorphous silicon layer is accomplished through excimer laser annealing.

4. The preparation method of claim 1, wherein the preparation method further comprises the following after forming the source/drain region of the low-temperature polysilicon transistor:
preparing a second stack structure on the patterned polysilicon layer and the patterned etch stop layer to complete the preparation of the low-temperature polysilicon transistor, wherein the second stack structure comprises a source/drain layer, a planarization layer, an anode layer, a pixel definition layer and a supporting layer.

5. The preparation method of claim 4, wherein preparing the second stack structure on the patterned polysilicon layer and the patterned etch stop layer comprises:
preparing a source/drain electrode layer on the patterned polysilicon layer and the patterned etch stop layer;
preparing a patterned planarization layer on the source/drain electrode layer;
preparing an anode layer, a pixel definition layer and a supporting layer in sequence on the patterned planarization layer.

6. The preparation method of claim 5, wherein the planarization layer, the pixel definition layer and the supporting layer are formed of an organic photoresist material.

7. The preparation method of claim 1, wherein preparing the first stack structure on the substrate comprises:
depositing a buffer layer and a gate layer in sequence on the substrate;
patterning the gate layer;
depositing a gate insulation layer on the buffer layer and the gate layer.

8. The preparation method of claim 7, wherein a material of the buffer layer and the etch stop layer is one of SiOx and SiNx.

9. A preparation method of a bottom-gate type low-temperature polysilicon transistor, wherein the preparation method comprises:
preparing a first stack structure on a substrate;
preparing a polysilicon layer and an etch stop layer in sequence on the first stack structure;
patterning the polysilicon layer and the etch stop layer at the same time so that the etch stop layer covers portions of the polysilicon layer;
implanting ions into the polysilicon layer that is not covered by the etch stop layer to form a source/drain region of the low-temperature polysilicon transistor.

10. The preparation method of claim 9, wherein patterning the polysilicon layer and the etch stop layer at the same time comprises:
patterning the polysilicon layer and the etch stop layer by using a semi-transmissive mask, regions of the semi-transmissive mask that correspond to the polysilicon layer having a light transmissivity different from that of regions of the semi-transmissive mask that correspond to the etch stop layer.

11. The preparation method of claim 9, wherein preparing the polysilicon layer on the first stack structure comprises:
depositing an amorphous silicon layer on the first stack structure;
crystallizing the amorphous silicon layer to transform the amorphous silicon layer into the polysilicon layer.

12. The preparation method of claim 11, wherein crystallizing the amorphous silicon layer is accomplished through excimer laser annealing.

13. The preparation method of claim 9, wherein the preparation method further comprises the following after forming the source/drain region of the low-temperature polysilicon transistor:
preparing a second stack structure on the patterned polysilicon layer and the patterned etch stop layer to complete preparation of the low-temperature polysilicon transistor, wherein the second stack structure comprises a source/drain layer, a planarization layer, an anode layer, a pixel definition layer and a supporting layer.

14. The preparation method of claim 13, wherein preparing the second stack structure on the patterned polysilicon layer and the patterned etch stop layer comprises:
preparing a source/drain electrode layer on the patterned polysilicon layer and the patterned etch stop layer;
preparing a patterned planarization layer on the source/drain electrode layer;
preparing an anode layer, a pixel definition layer and a supporting layer in sequence on the patterned planarization layer.

15. The preparation method of claim 14, wherein the planarization layer, the pixel definition layer and the supporting layer are formed of an organic photoresist material.

16. The preparation method of claim 9, wherein preparing the first stack structure on the substrate comprises:
depositing a buffer layer and a gate layer in sequence on the substrate;
patterning the gate layer;
depositing a gate insulation layer on the buffer layer and the gate layer.

17. The preparation method of claim 16, wherein a material of the buffer layer and the etch stop layer is one of SiOx and SiNx.

18. The preparation method of claim 9, wherein the ions are one of boron ions, bismuth ions, germanium ions, and cobalt ions.

19. A bottom-gate type low-temperature polysilicon transistor, comprising:
a substrate;
a first stack structure prepared on the substrate;
a polysilicon layer prepared on the first stack structure;
a etch stop layer prepared on the polysilicon layer;
wherein the polysilicon layer and the etch stop layer are patterned at the same time so that the etch stop layer covers portions of the polysilicon layer.

20. The polysilicon transistor of claim 19, wherein a material of the etch stop layer is one of SiOx and SiNx.
